(19) United States
(12) Patent Application Publication
(10) Pub. No.: US 2026/0172053 A1
(43) Pub. Date: Jun. 18, 2026

(54) DECODERS FOR QUANTUM LOW-DENSITY PARITY CHECK CODES USING MATCHING AND LOCAL CORRECTION

(71) Applicant: International Business Machines Corporation, Armonk, NY (US)

(72) Inventors: Benjamin James Brown, Copenhagen (DK); Kaavya Sahay, New Haven, CT (US)

(21) Appl. No.: 18/982,205

(22) Filed: Dec. 16, 2024

(51) Int. Cl. H03M 13/11

(52) U.S. Cl. CPC H03M 13/1148

(57) ABSTRACT

One or more systems, devices, computer program products and/or computer-implemented methods of use provided herein relate to decoding quantum low-density parity check (qLDPC) codes. For example, a system can comprise a memory that can store computer executable components and a processor that can execute the computer executable components stored in the memory. The computer executable components can comprise an error correction component that corrects, via a decoder, qubit errors for qLDPC code, wherein correcting qubit errors for the qLDPC code via the decoder can comprise: obtaining a set of local defect networks in a syndrome by matching defects on symmetries of the qLDPC code, wherein the symmetries comprise a subset of checks of the qLDPC code such that each qubit error creates an even number of defects; and locally correcting one or more of the set of local defect networks.

### BACKGROUND

The subject disclosure relates to quantum error correction and, more specifically, to a decoder for quantum low-density parity check codes using matching and local correction.

### SUMMARY

The following presents a summary to provide a basic understanding of one or more embodiments described herein. This summary is not intended to identify key or critical elements, delineate scope of particular embodiments or scope of claims. Its sole purpose is to present concepts in a simplified form as a prelude to the more detailed description that is presented later. In one or more embodiments described herein, systems, computer-implemented methods, apparatus and/or computer program products that enable decoding quantum low-density parity check (qLDPC) codes using matching and local correction are discussed.

According to an embodiment, a system is provided. The system can comprise a memory that can store computer executable components. The system can further comprise a processor that can execute the computer executable components stored in the memory, where the computer executable components can comprise an error correction component that corrects, via a decoder, qubit errors for quantum low-density parity-check (qLDPC) code, wherein correcting qubit errors for the qLDPC code via the decoder can comprise: obtaining a set of local defect networks in a syndrome by matching defects on symmetries of the qLDPC code, wherein the symmetries comprise a subset of checks of the qLDPC code such that each qubit error creates an even number of defects; and locally correcting one or more of the set of local defect networks.

According to various embodiments, the above-described system can be implemented as a computer-implemented method or as a computer program product.

### BRIEF DESCRIPTION OF THE DRAWINGS

One or more embodiments are described below in the Detailed Description section with reference to the following drawings:

FIG. 1 illustrates a block diagram of an example, non-limiting system that can facilitate a decoder for qLDPC codes using matching and local correction in accordance with one or more embodiments described herein.

FIG. 2 illustrates another block diagram of an example, non-limiting system that can facilitate a decoder for qLDPC codes using matching and local correction in accordance with one or more embodiments described herein.

FIG. 3 illustrates diagrams of example, non-limiting tanner graphs of a qLDPC code with qubit errors in accordance with one or more embodiments described herein.

FIG. 4 illustrates a diagram of an example, non-limiting symmetry and corresponding matching graph of qLDPC code in accordance with one or more embodiments described herein.

FIG. 5 illustrates a diagram of an example, non-limiting matching graph with matched edges in accordance with one or more embodiments described herein.

FIG. 6 illustrates diagrams of example, non-limiting symmetries of qLDPC code in accordance with one or more embodiments described herein.

FIG. 7 illustrates a diagram of an example, non-limiting local defect network in accordance with one or more embodiments described herein.

FIG. 8 illustrates a diagram of an example, non-limiting parity check matrices for extracting symmetries of qLDPC codes in accordance with one or more embodiments described herein.

FIG. 9 illustrates a diagram of an example, non-limiting performance results of decoding qLDPC codes using matching and local correction in accordance with one or more embodiments described herein.

FIG. 10 illustrates a flow diagram of an example, non-limiting method that can facilitate a decoder for qLDPC codes using matching and local correction in accordance with one or more embodiments described herein.

FIG. 11 illustrates a flow diagram of an example, non-limiting method that can facilitate a decoder for qLDPC codes using matching and local correction in accordance with one or more embodiments described herein.

FIG. 12 illustrates a flow diagram of an example, non-limiting method that can facilitate a decoder for qLDPC codes using matching and local correction in accordance with one or more embodiments described herein.

FIG. 13 illustrates a block diagram of an example, non-limiting operating environment in which one or more embodiments described herein can be facilitated.

### DETAILED DESCRIPTION

The following detailed description is merely illustrative and is not intended to limit embodiments and/or application or uses of embodiments. Furthermore, there is no intention to be bound by any expressed or implied information presented in the preceding Background or Summary sections, or in the Detailed Description section.

One or more embodiments are now described with reference to the drawings, wherein like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

According to an embodiment, a system is provided. The system can comprise a memory that can store computer executable components. The system can further comprise a processor that can execute the computer executable components stored in the memory, where the computer executable components can comprise an error correction component that corrects, via a decoder, qubit errors for qLDPC code, wherein correcting qubit errors for the qLDPC code via the decoder can comprise: obtaining a set of local defect networks in a syndrome by matching defects on symmetries of the qLDPC code, wherein the symmetries comprise a subset of checks of the qLDPC code such that each qubit error creates an even number of defects; and locally correcting one or more of the set of local defect networks.

Such embodiments of the system can provide a number of advantages, including reducing logical error rates in decoding, improving efficiency of decoding, and providing a procedure to obtain symmetries of bivariate bicycle codes.

In one or more embodiments of the aforementioned system, a graph construction component can construct matching graphs from the symmetries, wherein edges in the matching graphs represent qubit errors, and wherein vertices in the matching graphs represent checks of the qLDPC code.

Such embodiments of the system can provide the advantage of providing a procedure to obtain symmetries of bivariate bicycle codes. For example, the matching graphs can be used to match defects between different symmetries to form local defect networks.

In one or more embodiments of the aforementioned system, the graph construction component can obtain the symmetries from the qLDPC code using Gaussian elimination on a parity check matrix of the qLDPC code.

Such embodiments of the system can provide the advantage of providing a procedure to obtain symmetries of various qLDPC codes, and in particular, bivariate bicycle codes.

In one or more embodiments of the aforementioned system, obtaining the set of local defect networks can comprise matching the defects from different symmetries. Obtaining the set of local defect networks can further comprise combining the defects to form the set of local defect networks, wherein defects that share a qubit are in a same local defect network.

Such embodiments of the system can provide a number of advantages, including improving the speed of decoding qLDPC codes and improving logical error rates of decoding qLDPC codes.

In one or more embodiments of the aforementioned system, locally correcting one or more of the set of local defect networks can comprise obtaining a loop of edges in a local defect network. Locally correcting one or more of the set of local defect networks can further comprise selecting a check on the loop of edges. Locally correcting one or more of the set of local defect networks can further comprise traversing the loop of edges starting from the check to determine a correction operator.

Such embodiments of the system can provide a number of advantages, including improving the speed of decoding qLDPC codes and improving logical error rates of decoding qLDPC codes.

In one or more embodiments of the aforementioned system, the error correction component can include edges from the loop of edges in the correction operator if it cancels defects in the syndrome.

Such embodiments of the system can provide a number of advantages, including improving the speed of decoding qLDPC codes and improving logical error rates of decoding qLDPC codes.

In one or more embodiments of the aforementioned system, the error correction component can traverse the loop of edges starting from different checks on the loop of edges until the qubit errors match the defects.

Such embodiments of the system can provide a number of advantages, including reducing the overhead involved in performing a logical measurement in a quantum stabilizer code and providing a fault distance guarantee.

In one or more embodiments of the aforementioned system, the correction operator can be a Pauli operator that corrects the defects in the local defect network.

Such embodiments of the system can provide a number of advantages, including improving the speed of decoding qLDPC codes and improving logical error rates of decoding qLDPC codes.

In one or more embodiments of the aforementioned system, the error correction component can match, based on the matching graphs, the defects via minimum-weight perfect matching, union-find decoding, weighted union-find decoding, clustering, or belief matching.

Such embodiments of the system can provide a number of advantages, including providing a flexible procedure to match defects between symmetries of qLDPC codes.

According to various embodiments, the above-described system can be implemented as a computer-implemented method or as a computer program product.

### DEFINITIONS

Qubit: A qubit is a two-level quantum system and the basic unit of quantum information.

Quantum error correcting (QEC) code: QEC code is a redundant encoding of logical quantum information using logical qubits.

Check: A check is a measurement used to detect errors in a QEC code.

Syndrome: A syndrome is the observed result of measuring a check.

Defect: A defect is a detection of an error by the measurement of a check.

qLDPC codes: The qLDPC codes are a family of QEC codes where physical qubits have limited, constant connectivity to checks.

Bivariate Bicycle code (Gross code): The Bivariate Bicycle code is a family of qLDPC codes characterized by a bipartite graph structure, where each variable node is connected to exactly two check nodes.

Decoder: A decoder is an algorithm that uses information of defects to correct errors on the physical qubits that make up a QEC code.

Belief Propagation with Ordered Statistics Decoding (BP-OSD) decoder: A BP-OSD decoder is a decoder based on matrix inversion.

Tanner graph: A tanner graph is the bipartite connectivity graph between checks and qubits in a code.

In quantum computing, quantum error correction is central to the preservation of quantum information during a computation on noisy physical qubits. A QEC code is a structure of qubits designed to work together to protect encoded data by performing measurements, called checks, to detect errors. These checks provide syndrome information, revealing where errors have occurred in the quantum system. A decoder processes this syndrome information, identifies the locations of defects, and determines how to correct the errors. A defect is detected when a check identifies an error. The decoder is a classical algorithm that produces a correction to enable recovery of the information stored in the QEC code. Since error patterns can vary widely, the decoder is tasked to find the best correction strategy. The performance of the decoder can be measured in terms of runtime and the number of errors it can successfully correct.

Quantum low-density parity-check (qLDPC) codes, such as the Bivariate Bicycle (BB) code, are especially important for their structured design, which allows for efficient error correction in quantum systems. Their sparse graphical structure facilitates scalable implementations, making them suitable for larger quantum systems. Additionally, efficient and effective decoders for qLDPC codes are crucial because they directly affect the overall effectiveness of error correction. That is, efficient decoders ensure that errors are corrected promptly, thereby enhancing the reliability of quantum computations and enabling practical applications in quantum computing.

Existing methods for decoding qLDPC codes utilize BP-OSD decoder. However, the BP-OSD decoder has shown limitations in practice, particularly in its inability to correct certain errors that, theoretically, should be manageable. For instance, the BP-OSD decoder struggles with specific patterns of correlated errors, such as clusters of errors occurring in adjacent qubits or errors that propagate through the code structure in a way that should be detectable. Existing methods for decoding with BP-OSD miss correctable errors or make suboptimal correction choices for specific error patterns. Furthermore, the Ordered Statistics Decoding component of the BP-OSD decoder can be slow, which can hinder overall performance and efficiency in real-time applications. This is due to its reliance on exhaustive searches to evaluate multiple decoding paths and determine the optimal correction for detected errors. This computational intensity increases with larger code sizes and the need to rank potential error patterns, limiting the practicality of OSD in real-time applications. Thus, methods for efficiently decoding qLDPC codes with improved runtime and error rates are desirable.

Various embodiments of the present disclosure can be implemented to produce a solution to these problems. Embodiments described herein include systems, computer-implemented methods, and computer program products that provide a decoder for quantum qLDPC codes by creating local defect networks of a syndrome and locally correcting the local defect networks. The methods and techniques decribed herein can decode qLDPC codes with faster runtimes than BP-OSD and can correct errors that the BP-OSD decoder fails to correct. Thus, the various emboidiments described herein can allow efficient and effective decoding of qLDPC codes. Particularly, the various embodiments described herein can be employed for decoding BB codes by enabling the determination of symmetries of BB codes. A symmetry is a subset of checks of a qLDPC code such that each qubit error creates an even number of defects in the symmetry. Thus, the local defect networks can be obtained by matching defects on symmetries of a BB code, providing a new and more efficient approach to decode BB codes.

In comparison to existing methods, the embodiments described herein for decoding qLDPC codes can improve overhead costs by reducing runtime. Such reduced runtime results from the fact that symmetries of the qLDPC codes can be obtained to form local defect networks which can be locally corrected. On the contrary, many existing methods, such as BP-OSD utilize matrix inversion, which is cubic in the number of qubits n, and therefore can result in slower runtimes. In the various embodiments of the present disclosure, the ability to obtain symmetries of the qLDPC codes, and particularly BB codes, can provide the advantage of simplifying the decoding problem and the ability to leverage the symmetries to identify equivalent error patterns, reducing the computational complexity for decoding. These advantages are described in greater detail with reference to one or more figures, where decoding for explicit instances of BB codes that have improved error correction than existing methods have been identified.

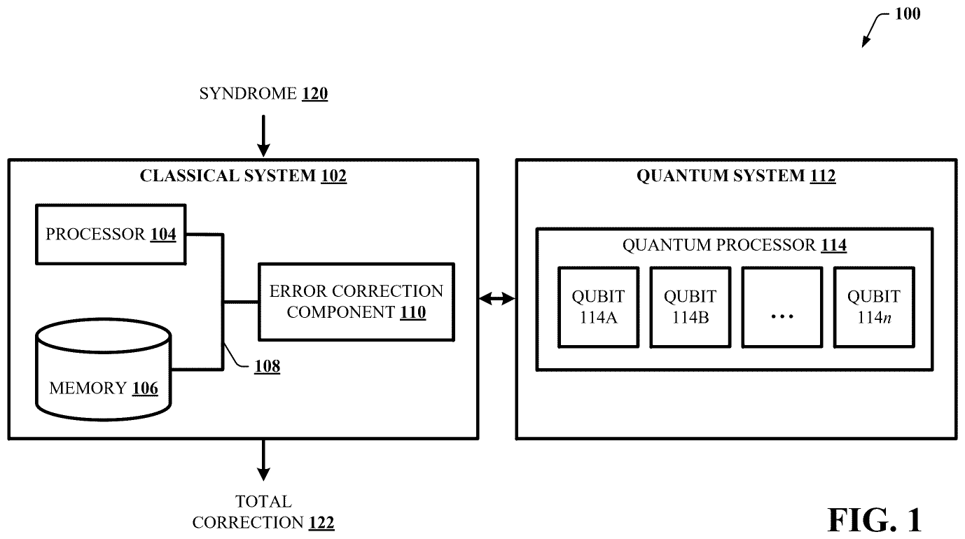

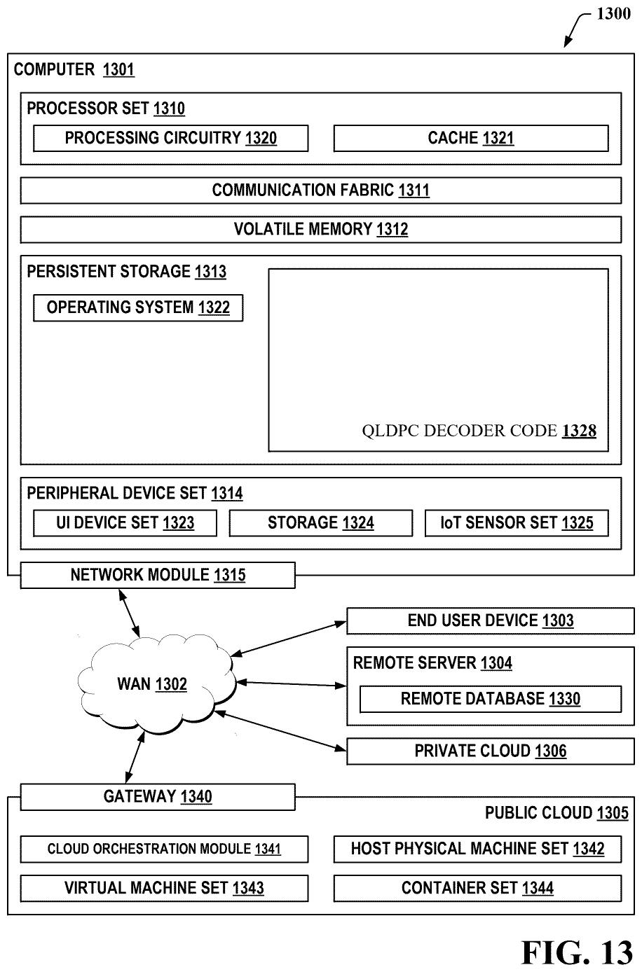

The embodiments depicted in one or more figures described herein are for illustration only, and as such, the architecture of embodiments is not limited to the systems, devices and/or components depicted therein, nor to any particular order, connection and/or coupling of systems, devices and/or components depicted therein. For example, in one or more embodiments, the non-limiting systems described herein, such as non-limiting system 100 as illustrated at FIG. 1, and/or systems thereof, can further comprise, be associated with and/or be coupled to one or more computer and/or computing-based elements described herein with reference to an operating environment, such as the operating environment 1300 illustrated at FIG. 13. For example, non-limiting system 100 can be associated with, such as accessible via, a computing environment 1300 described below with reference to FIG. 13, such that aspects of processing can be distributed between non-limiting system 100 and the computing environment 1300. In one or more described embodiments, computer and/or computing-based elements can be used in connection with implementing one or more of the systems, devices, components and/or computer-implemented operations shown and/or described in connection with FIG. 1 and/or with other figures described herein.

For simplicity of explanation, the computer-implemented and non-computer-implemented methodologies provided herein are depicted and/or described as a series of acts. It is to be understood that the subject innovation is not limited by the acts illustrated and/or by the order of acts, for example acts can occur in one or more orders and/or concurrently, and with other acts not presented and described herein. Furthermore, not all illustrated acts can be utilized to implement the computer-implemented and non-computer-implemented methodologies in accordance with the described subject matter. Additionally, the computer-implemented methodologies described hereinafter and throughout this specification are capable of being stored on an article of manufacture to enable transporting and transferring the computer-implemented methodologies to computers. The term article of manufacture, as used herein, is intended to encompass a computer program accessible from any computer-readable device or storage media.

The systems and/or devices have been (and/or will be further) described herein with respect to interaction between one or more components. Such systems and/or components can include those components or sub-components specified therein, one or more of the specified components and/or sub-components, and/or additional components. Sub-components can be implemented as components communicatively coupled to other components rather than included within parent components. One or more components and/or sub-components can be combined into a single component providing aggregate functionality. The components can interact with one or more other components not specifically described herein for the sake of brevity, but known by those of skill in the art.

FIG. 1 illustrates a block diagram of an example, non-limiting system 100 that can facilitate a decoder for qLDPC codes using matching and local correction in accordance with one or more embodiments described herein.

Non-limiting system 100 and/or the components of non-limiting system 100 can be employed to use hardware and/or software to solve problems that are highly technical in nature (e.g., related to decoding qLDPC codes using matching and local correction, quantum error correction, BB codes, etc.), that are not abstract and that cannot be performed as a set of mental acts by a human. Further, some of the processes performed may be performed by specialized computers for carrying out defined tasks related to decoding qLDPC codes using matching and local correction. Non-limiting system 100 and/or components of non-limiting system 100 can be employed to solve new problems that arise through advancements in technologies mentioned above, computer architecture, and/or the like. Non-limiting system 100 can provide technical improvements to quantum computing systems by improving the overhead involved in decoding qLDPC codes, improving logical error rates in qLDPC codes, providing a providing a procedure to obtain symmetries of BB codes, etc.

Discussion turns briefly to processor 104, memory 106 and bus 108 of non-limiting system 100. For example, in one or more embodiments, non-limiting system 100 can comprise processor 104 (e.g., computer processing unit, microprocessor, classical processor, and/or like processor). In one or more embodiments, a component associated with non-limiting system 100, as described herein with or without reference to the one or more figures of the one or more embodiments, can comprise one or more computer and/or machine readable, writable and/or executable components and/or instructions that can be executed by processor 104 to enable performance of one or more processes defined by such component(s) and/or instruction(s).

In one or more embodiments, non-limiting system 100 can comprise a computer-readable memory (e.g., memory 106) that can be operably connected to processor 104. Memory 106 can store computer-executable instructions that, upon execution by processor 104, can cause processor 104 and/or one or more other components of non-limiting system 100 (e.g., error correction component 110, matching component 202, local correction component 204, and/or graph construction component 206) to perform one or more actions. In one or more embodiments, memory 106 can store computer-executable components (e.g., error correction component 110, matching component 202, local correction component 204, and/or graph construction component 206).

Non-limiting system 100 and/or a component thereof as described herein, can be communicatively, electrically, operatively, optically and/or otherwise coupled to one another via bus 108. Bus 108 can comprise one or more of a memory bus, memory controller, peripheral bus, external bus, local bus, and/or another type of bus that can employ one or more bus architectures. One or more of these examples of bus 108 can be employed. In one or more embodiments, non-limiting system 100 can be coupled (e.g., communicatively, electrically, operatively, optically and/or like function) to one or more external systems (e.g., a non-illustrated electrical output production system, one or more output targets, an output target controller and/or the like), sources and/or devices (e.g., classical computing devices, communication devices and/or like devices), such as via a network. In one or more embodiments, one or more of the components of non-limiting system 100 can reside in the cloud, and/or can reside locally in a local computing environment (e.g., at a specified location(s)).

As illustrated in FIG. 1, non-limiting system 100 can comprise classical system 102 and quantum system 112. Classical system 102 can be coupled (operatively, communicatively, electrically, and/or like function) to quantum system 112. Quantum system 112 can comprise at least one quantum processor, such as quantum processor 114. Classical system 102 can comprise one or more components, such as a memory 106, processor 104, bus 108, and/or error correction component 110. In an embodiment, error correction component 110 can be comprised at least partially by quantum system 112. Quantum processor 114 can comprise a quantum logic circuit comprising one or more qubits, such as qubit 114A, qubit 114B, . . . , qubit 114n, etc., where n represents a positive integer. Quantum processor 114 can be any suitable processor. Quantum processor 114 can generate one or more instructions for controlling the quantum logic circuit.

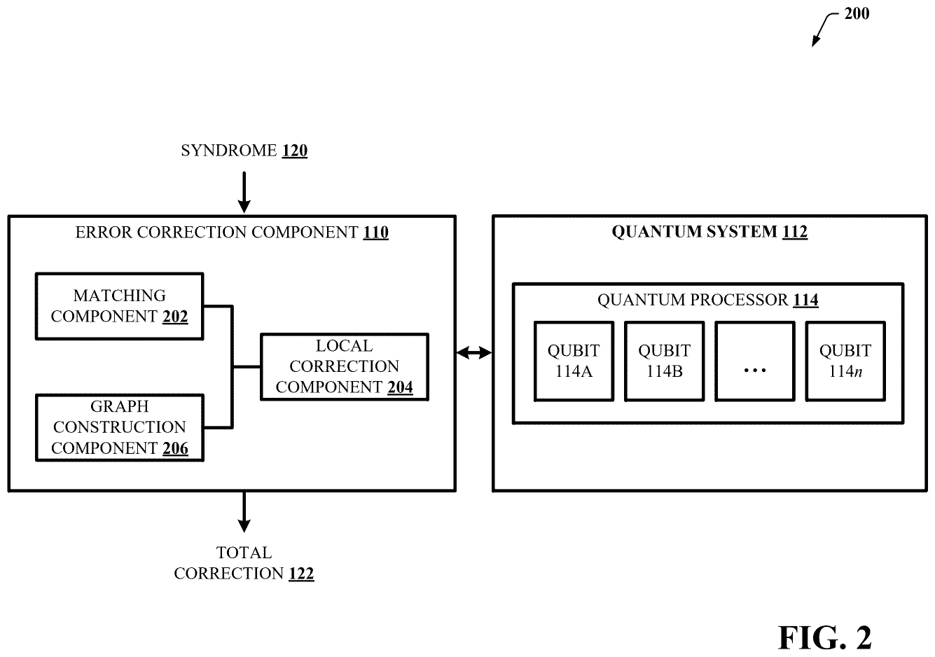

In various embodiments, error correction component 110 can comprise matching component 202, local correction component 204, and graph construction component 206, as illustrated in FIG. 2. In various embodiments, matching component 202 can receive a syndrome 120 and obtain a set of local defect networks. In various aspects, matching component 202 can receive syndrome 120 from quantum system 112 resulting from quantum operations. In various embodiments, graph construction component 206 can construct corresponding matching graphs for the symmetries of the qLDPC code, from which the matching component 202 can match defects to create the set of local defect networks. In various embodiments, matching component 202 can employ any suitable method to match defects across the symmetries, such as minimum-weight perfect matching, union-find decoding, weighted union-find decoding, clustering, or belief matching. In various embodiments, local correction component 204 can locally correct each of the local defect networks. That is, local correction component 204 can determine a correction operator that corrects the defects in the local defect networks. For example, local correction component 204 can locally correct a local defect network by traversing loops of edges in the local defect network to determine a correction operator that cancels the defect in the syndrome 120. The local corrections obtained from the local defect networks can then be outputted as a total correction 122 for syndrome 120.

FIG. 2 illustrates a block diagram of an example, non-limiting system 200 that can facilitate a decoder for qLDPC codes using matching and local correction in accordance with one or more embodiments described herein. Repetitive description of like elements and/or processes employed in respective embodiments is omitted for sake of brevity.

As described with reference to FIG. 1, error correction component 110 can comprise matching component 202, local correction component 204, and graph construction component 206. In this regard, non-limiting system 200 describes the system of error correction component 110 and quantum system 112 that can correct qubit errors of syndrome 120 for qLDPC codes via a decoder.

Embodiments described herein provide a decoder for qLDPC codes that can generate exhibit improved runtume and improved error correction in some cases. For example, in various embodiments, error correction component 110 can determine symmetries of a qLDPC code. For example, error correction component 110 can determine symmetries of a BB code using Guassian elimination. Upon determination of the symmetries, error correction component 110 can match defects on the symmetries based on corresponding matching graphs of the symmetries. By matching the defects on the symmetries, error correction component 110 can create local defect networks based on the matchings of the defects. For example, error correction component 110 can group defects of different symmetries that share a qubit into a local defect network. By matching the defcts to form the local defect networks, error correction component 110 can efficiently determine a correction for syndrome 120 in parts, rather than determining a total correction for syndrome 120, which can be more challenging for the decoder. In other words, dividing syndrome 120 into the local defect networks, error correction component 110 can simplify the decoding problem by individually finding a correction for each local defect network. For example, the local correction of the local defect networks can be performed by traversing loops of edges in the local defect networks. Upon completion of traversal, error correction component 110 can output the correction for the local defect network or, convresely, can ouput a hearalded failure (e.g., the decoder is unable to determine a correction).

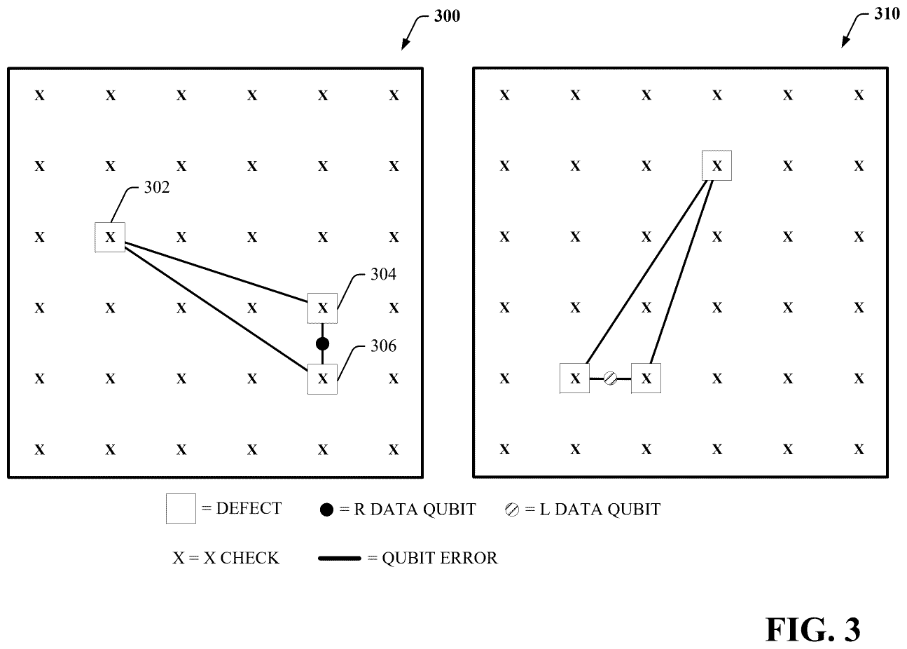

FIG. 3 illustrates diagrams of example, non-limiting tanner graphs 300 and 310 of a qLDPC code with qubit errors in accordance with one or more embodiments described herein. Repetitive description of like elements and/or processes employed in respective embodiments is omitted for sake of brevity.

Non-limiting tanner graphs 300 and 310 depict a qubit error that creates defects on checks of a qLDPC code. As shown, the checks of the qLDPC code are depicted by an ‘x’, and checks contained in a box represent checks that are affected by a qubit error. In other words, the box can represent a defect on the check. The edges between checks with a defect represent the qubit error that creates the defects. The qLDPC code can comprise R data qubits and L data qubits. In BB codes, a qubit error creates 3 defects. Furthermore, qubit errors of R data qubits can create different patterns of syndromes (e.g., error patterns) or different orientations of syndromes than qubit errors of L data qubits. For example, in non-limiting tanner graph 300, a qubit error of an R data qubit can cause a defect on 3 checks (e.g., on check 302, check 304, and check 306). As another example, in non-limiting tanner graph 310, a qubit error of an L data qubit can cause a defect on 3 checks with the depicted orientation. As shown, the 3 checks in any qubit error can be connected by edges that represent the qubit error on the R data qubit.

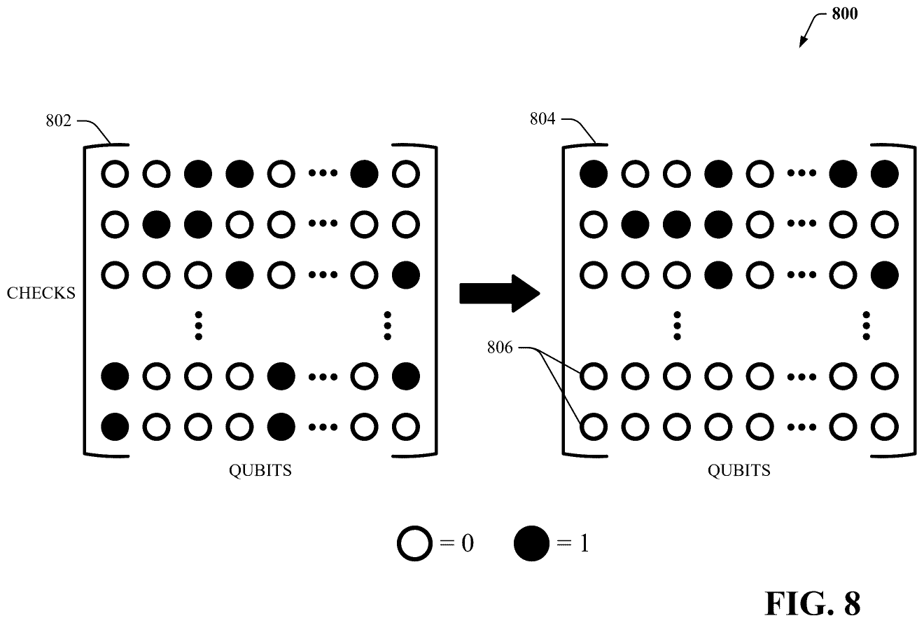

Existing approaches have yet to propose a method to obtain symmetries of BB codes where each error generates 3 defects. Thus, typical matching techniques cannot be applied. By employing Guassian elimination, as described with respect to FIG, 8, a set of symmetries can be obtained from the BB code that can facilitate matching of defects, overcoming the limitations of existing approaches. Various aspects of determining symmeteries of BB codes are described with respect to FIG. 8.

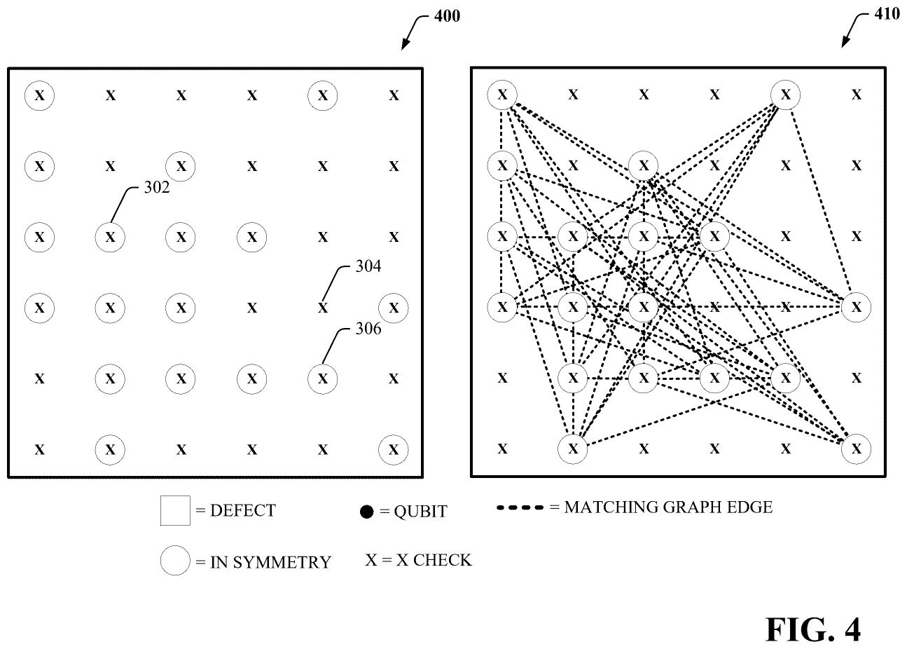

FIG. 4 illustrates a diagram of an example, non-limiting symmetry 400 and corresponding matching graph 500 of qLDPC code in accordance with one or more embodiments described herein. Repetitive description of like elements and/or processes employed in respective embodiments is omitted for sake of brevity.

In various embodiments, matching component 202 can determine symmetries of qLDPC codes. For example, matching component 202 can extract non-limiting symmetry 400 from a qLDPC code. As stated with reference to FIG. 1, a symmetry is a subset of checks of a qLDPC code such that each qubit error creates an even number of defects in the symmetry. For BB codes specifically, each error creates 2 defects in the symmetry. By obtaining symmetries of BB codes such that each error creates 2 defects, the structure of the symmetries can be leveraged to employ matching subroutines (e.g., algorithms, methods, procedures) to pair the defects to determine a local correction.

As shown, the non-limiting symmetry 400 can comprise a subset of 18 checks, which are depicted by the circled checks. However, the symmetries can comprise any suitable number of checks in the subset (e.g., any subset that results from Gaussian elimination or any other method to obtain the symmetries). For instance, as described with reference to FIG. 8, Gaussian elimination resulted in subsets comprising 16 checks and subsets comprising 18 checks for BB code [[72,12,6]].

In various embodiments, graph construction component 206 can construct a matching graph for each symmetry. That is, each symmetry can correspond to a matching graph. For example, graph construction component 206 can construct non-limiting matching graph 410 that corresponds to non-limiting symmetry 400. The edges of non-limiting matching graph 410 that connect the subset of checks in non-limiting symmetry 400 are illustrated by dashed lines.

In various embodiments, graph construction component 206 can construct non-limiting matching graph 410 by adding an edge between 2 checks in the symmetry based on the qubit errors. That is, for every qubit error with respect to non-limiting symmetry 400, graph construction component 206 can add an edge between the two checks that are defected from the qubit error. In other words, for every qubit error that creates a pair of defects on the checks in the symmetry, graph construction component 206 can add an edge between the pair of checks. In this way, the nodes of the matching graphs can represent defects and the edges of the matching graphs can represent qubit errors that create defects on the checks of the qLDPC code.

For example, graph construction component 206 can add an edge between two checks based on the qubit error depicted in non-limiting tanner graph 300. The qubit error in non-limiting tanner graph 300 creates a defect on 3 checks, however, only two checks are within non-limiting symmetry 400. More specifically, the qubit error creates a defect on check 302, check 304, and check 306. However, non-limiting symmetry 400 only comprises check 302 and check 304. Therefore, graph construction component 206 can add an edge between the two checks that are in non-limiting symmetry 400, which is check 302 and check 304. In various embodiments, graph construction component 206 can repeat such process until all edges are added to generate non-limiting matching graph 410.

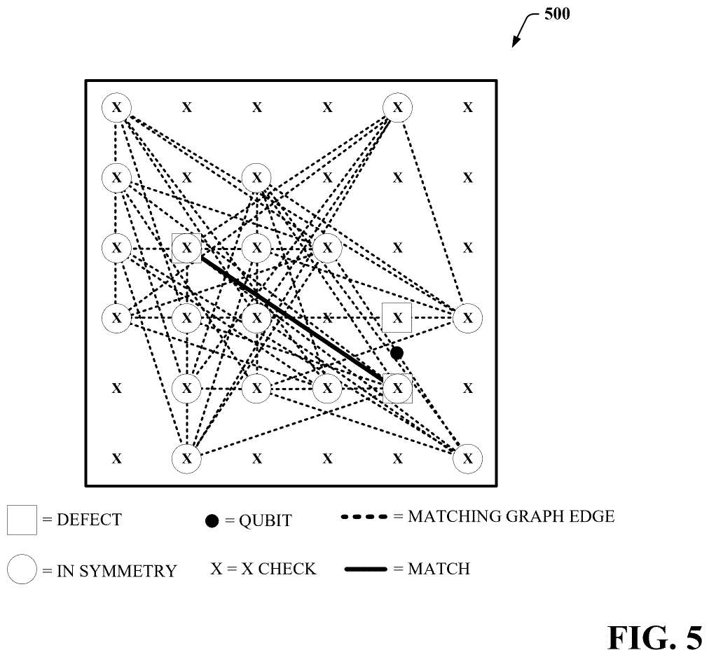

FIG. 5 illustrates a diagram of an example, non-limiting matching graph 500 with matched edges in accordance with one or more embodiments described herein. Repetitive description of like elements and/or processes employed in respective embodiments is omitted for sake of brevity.

In various embodiments, matching component 202 can utilize the matching graphs that correspond to the symmetries to match defects between the symmetries. In other words, matching component 202 can match the defects on the symmetries along the matching graphs to determine clusters (networks) of correctable defects. For example, non-limiting matching graph 500 depicts a matched edge, illustrated by a solid line, resulting from a matching subroutine on non-limiting matching graph 410. In various aspects, matching component 202 can match the defects based on the matching graphs via any suitable matching subroutine.

As a non-limiting example, matching component 202 can match the defects using minimum-weight perfect matching on the matching graphs of the symmetries. In various aspects, matching component 202 can assign a weight to each edge in the matching graphs. For example, matching component 202 can determine the weights based on error probabilities of the qubit error (e.g., likelihood of the error occurring on physical qubits). In this case, higher error probabilities can be assigned lower weights. In other instances, matching component 202 can determine the weights based on physical distances between the defects (e.g., the number of qubits between two defects). In this case, larger distances can correspond to higher weights. In any instance, matching component 202 can find a set of defect pairs across symmetries that minimizes a total edge weight. In various aspects, matching component 202 can pair all defects for perfect matching such that the total weight of edges connecting the paired nodes is minimized.

As another non-limiting example, matching component 202 can match the defects using union-find decoding on the matching graphs of the symmetries. Union-find decoding can match defects across symmetries by grouping the defects into clusters. In various aspects, matching component 202 can first treat each defect as its own cluster. Then, in various embodiments, matching component 202 can expand the clusters around each defect by adding edges (qubits) of the matching graph. As the clusters expand, matching component 202 can search for other defects within a defined radius (e.g., radius-1 where defects are 1 qubit away from the defect, radius-2 where defects are 2 qubits away from the defect). If two clusters meet (e.g., overlap or encounter each other), matching component 202 can merge the clusters via a union operator. Before merging two clusters, matching component 202 can perform a find operation to determine the root of each cluster. In various aspects, matching component 202 can stop expanding a cluster when all defects in a merged cluster are surrounded by valid checks (checks without a defect). When clusters meet, matching component 202 can identify the edges between the defects to be matched. In various embodiments, matching component 202 can merge smaller clusters to the larger clusters to implement weighted union-find decoding on the matching graphs of the symmetries. Weighted union-find decoding can improve efficiency of matching by maintaining a shallower tree structure of the clusters. Specifically, find and union operations can be more efficient due to the minimized height of the tree structure.

As still another non-limiting example, matching component 202 can match the defects using clustering on the matching graphs of the symmetries. Clustering can group defects based on their proximity or connectivity, allowing for a more flexible approach to identifying related defects. In various aspects, matching component 202 can first initialize each defect as its own independent cluster. Then, in various embodiments, matching component 202 can expand the clusters around each defect by incorporating nearby edges (qubits) of the matching graph. As clusters grow, matching component 202 can search for other defects within a defined radius. If two clusters meet, matching component 202 can merge them into a single larger cluster based on proximity. In various aspects, matching component 202 can stop expanding a cluster when all defects in a merged cluster are surrounded by valid checks. When clusters meet, matching component 202 can identify the edges between the defects to be matched.

As even another non-limiting example, matching component 202 can match the defects using belief matching on the matching graphs of the symmetries. In various aspects, matching component 202 can assign a probability or belief value to each defect in the matching graphs, where each belief value represents a likelihood that a corresponding error occurred. In various embodiments, matching component 202 can first initialize each defect with an associated belief value derived from observed syndromes. Then, the belief values can be iteratively updated, by matching component 202, based on correlations between the defects and the matching graphs. During belief matching, matching component 202 can assess the belief values to determine which defects are likely to be associated with the same error. When pairs of defects are identified with high belief values indicating a strong correlation, matching component 202 can connect them as matched edges.

Note that, these are non-limiting examples to match defects across the symmetries, and that any suitable matching subroutine can be employed.

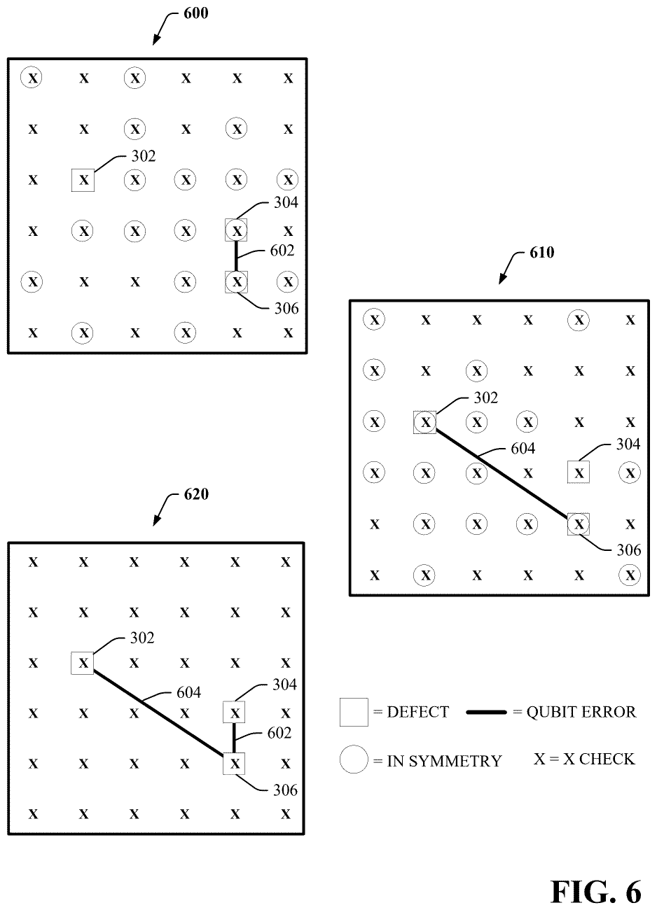

FIG. 6 illustrates diagrams of example, non-limiting symmetries 600 and 610 of qLDPC code in accordance with one or more embodiments described herein. Repetitive description of like elements and/or processes employed in respective embodiments is omitted for sake of brevity.

No matter the matching subroutine used, matching component 202 can determine the local defect networks based on the matched defects. A local defect network can be defined such that if two defects share a qubit, then the defects belong to the same local defect network. Furthermore, the edge that connects the two defects belongs to the same local defect network.

For example, there can be non-limiting symmetry 600 and non-limiting symmetry 610. As shown, there can be a matched edge 602 on non-limiting symmetry 600 and a matched edge 604 on non-limiting symmetry 610. Matched edge 602 can connect check 304 and check 306. Matched edge 604 can connect check 302 and check 306. Since, based on the qubit error illustrated in non-limiting tanner graph 300, the defects on check 304 and check 306 share a qubit, they will belong to the same local defect network, including matched edge 602. Similarly, since the defects on check 302 and check 306 share a qubit, they will belong to the same local defect network, including matched edge 604. Resulting from the matched edges in non-limiting symmetries 600 and 610 is non-limiting local defect network 620. More specifically, the non-limiting local defect network 620 can comprise check 302, check 304, check 306, matched edge 602, and matched edge 604.

In various embodiments, matching component 202 can obtain the local defect networks by matching and combining defects across any number of symmetries of the qLDPC code. Accordingly, local correction component 204 can determine a local correction for each of the local defect networks.

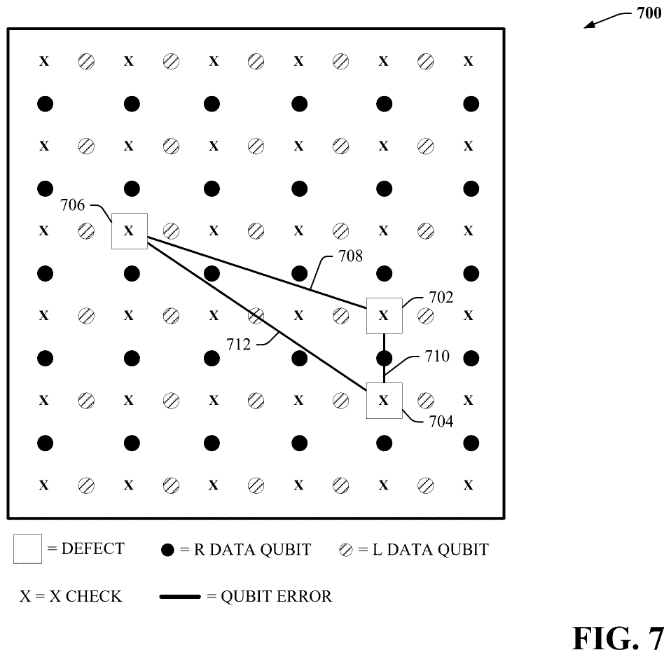

FIG. 7 illustrates a diagram of an example, non-limiting local defect network 700 in accordance with one or more embodiments described herein. Repetitive description of like elements and/or processes employed in respective embodiments is omitted for sake of brevity.

The various embodiments described herein provide a method for dividing the syndrome 120 into correctable local defect networks. This can simplify the decoding problem by individually determining correction for each local defect network as opposed to a total correction for the syndrome 120. In various aspects, local correction component 204 can utilize any suitable method to determine local corrections of the local defect networks. For example, in various embodiments, one or more of the local defect networks can comprise loops of edges between checks, which local correction component 204 can traverse to determine the local corrections.

An algorithm to facilitate determination of local corrections of the local defect networks can be elaborated as follows.

In various embodiments, local correction component 204 can receive a loop L (e.g., loop of edges) and a syndrome σ (e.g., syndrome 120). In various aspect, local correction component 204 can select a check on loop L to be used as a starting point for traversal. In various instances, selection of the check can be random. For example, local correction component 204 can select check 706 as the starting point for traversal. Following selection of the starting point check, local correction component 204 can traverse an edge in loop L. For example, local correction component 204 can traverse edge 708. When traversing an edge, local correction component 204 can flip a qubit along the loop if it cancels elements in syndrome σ. Conversely, if the qubit does not cancel elements in syndrome σ, local correction component 204 can skip the qubit. Following traversal of the edge, local correction component 204 can traverse the next edge in loop L. For example, local correction component 204 can traverse edge 710 following traversal of edge 708. For each edge traversal, local correction component 204 can flip qubits if it cancels elements in syndrome σ. If at any point in traversal of loop L the syndrome σ converges, local correction component 204 can output the local correction of the local defect network that contains loop L.

Further, if local correction component 204 traverses all edges in loop L, returning to the starting point check, and if the syndrome σ has not converged, local correction component 204 can begin traversal of loop L from a different starting point. For example, if local correction component 204 began traversal from check 706 and traversed edge 708, edge 710, and edge 712 without syndrome σ converging, local correction component 204 can select check 702 or check 704 as the next starting point. Accordingly, local correction component 204 can traverse loop L as previously described. If all checks in loop L have been used as a starting point and all corresponding traversals have been completed with syndrome σ not converged, local correction component 204 can traverse a different loop in the local defect network. If there are no remaining loops in the local defect network, local correction component 204 can output a heralded failure, indicating that a correction cannot be found.

In various embodiments, during traversal of the local defect networks, if a qubit (edge) is flipped and cancels defects associated with the local defect network, local correction component 204 can include the qubit in a local correction operator for the local defect network. In various instances, the local correction operators can be a Pauli operator. In various aspects, the local correction operators for each local defect network can be outputted as the total correction 122 for the syndrome 120. The local correction operators (Pauli operators) can then correct the defects in each of the local defect networks, thus correcting the qubit errors from syndrome 120.

In various embodiments, local correction component 204 can traverse any sets of edges in the local defect networks to determine the local correction operators. That is, traversal of the edges does not require loops of edges to determine the local corrections. In various aspects, local correction component 204 can utilize any suitable method to traverse the local defect networks to determine the local correction operators.

Note that, the local correction algorithm described is a non-limiting example to determine a local correction for each local defect network, and that any suitable local correction subroutine can be employed.

FIG. 8 illustrates a diagram of an example, non-limiting parity check matrices 800 for extracting symmetries of qLDPC codes in accordance with one or more embodiments described herein. Repetitive description of like elements and/or processes employed in respective embodiments is omitted for sake of brevity.

Non-limiting parity check matrices 800 are intended to describe additional aspects of extracting symmetries for qLDPC codes, and particularly for BB codes.

As stated with reference to FIG. 2, matching component 202 can obtain the symmetries of the qLDPC code using various methods such as Gaussian elimination. In this regard, matching component 202 can perform Gaussian elimination on a parity check matrix 802 (parity check matric H) of the qLDPC code. A parity check matrix is a binary matrix that defines the relationships between encoded data and the checks (parity checks). The parity check matrix 802 can have n×n elements, where n denotes the number of physical qubits, and can have a rank of (n−k), where k denotes the number of logical qubits that are encoded. The rows of parity check matrix 802 can represent the checks of the qLDPC code, and the columns of parity check matrix 802 can represent the physical qubits. An entry of 0 in the parity check matrix 802 indicates that a check does not have support on a qubit, and an entry of 1 in the parity check matrix 802 indicates that a check has support on a qubit. For example, element (i, j) of parity check matrix 802 can indicate if the i-th check has support on the j-th qubit.

In various embodiments, matching component 202 can perform Gaussian elimination on parity check matrix 802 to determine a row reduced parity check matrix 804 (row reduced parity check matrix PH, where P denotes a permutation operator), wherein bottom k rows 806 of row reduced parity check matrix 804 only has entries of 0. In various aspects, performing Gaussian elimination on parity check matrix 802 can involve applying the permutation operator P to parity check matrix 802 to reorder rows to position a non-zero pivot element in the leading diagonal of each row. Gaussian elimination can further comprise performing row operations on the parity check matrix PH to create zeros below each pivot element, transforming the parity check matrix PH into row echelon form. Following transformation of the parity check matrix PH into row echelon form, matching component 202 can use back substitution to further simplify the parity check matrix PH to row reduced parity check matrix 804. Accordingly, with the identification of P, the bottom k rows 806 of row reduced parity check matrix 804 thus correspond to the symmetries of the qLDPC code. That is, each row in the bottom k rows 806 corresponds to a symmetry. In the row reduced parity check matrix 804, the checks (represented by the rows) are ordered according to an ordering of the checks in the rows of parity check matrix 802. In various embodiments, an entry of 0 in the row reduced parity check matrix 804 indicates the exclusion of a check in a symmetry, and an entry of 1 indicates the inclusion of a check in a symmetry. For example, in the row reduced parity check matrix 804, each check in the bottom k rows 806 is excluded from the symmetry.

In various embodiments, matching component 202 can generate additional symmetries using the k symmetries identified from the permutation operator P. More specifically, matching component 202 can add two symmetries from the k symmetries modulo 2 to obtain an additional symmetry. The k symmetries can be considered as generating symmetries, from which the additional symmetries can be determined. For example, in the BB code [[72,12,6]], Gaussian elimination on the parity check matrix 802 resulted in 6 generating symmetries, which can be used to determine 64 symmetries in total. In various embodiments, matching component 202 can select a subset of the symmetries of the qLDPC code to match defects between for obtaining the set of local defect networks. In various cases, matching component 202 can select the subset of the symmetries based on a structure of the local defect networks that result from the symmetries. For example, the local defect networks that result from 8 of the 64 symmetries can facilitate traversal of loops of edges for determining local corrections as described with respect to FIG. 7. Accordingly, matching component 202 can select the 8 symmetries as the subset and match defects between the 8 symmetries.

Existing approaches have yet to propose a method to obtain symmetries of BB codes. In BB codes, each error generates 3 defects. Thus, typical matching techniques cannot be applied. By employing Guassian elimination on the parity check matrix H of a BB code, a set of symmetries can be obtained from the BB code that can facilitate matching of defects, overcoming the limitations of existing approaches. This is due to the fact that the symmetries comprise a subset of the checks of the qLDPC code where every error creates an even number if defects. For BB codes in particular, the symmetries comprise a subset of the checks of the BB code where every error creates 2 defects.

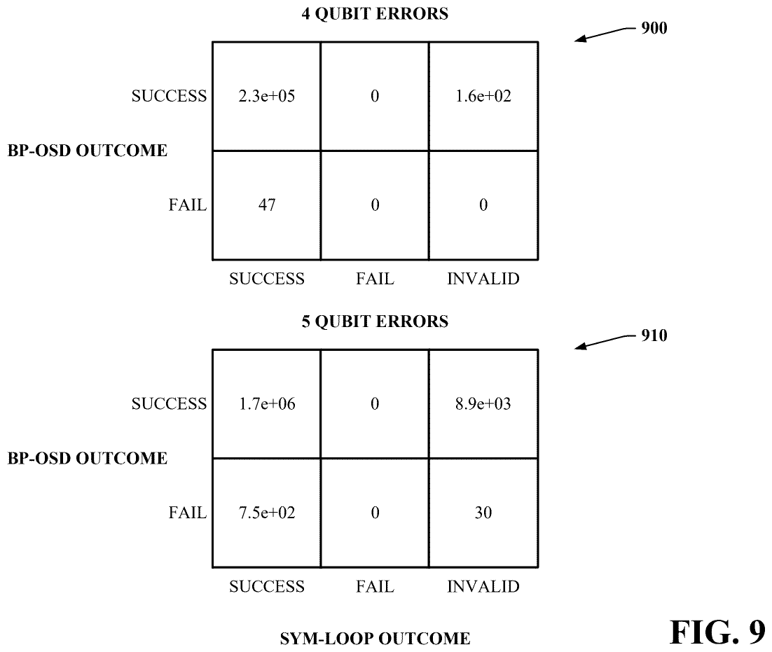

FIG. 9 illustrates a diagram of an example, non-limiting performance results 900 and 910 of decoding qLDPC codes using matching and local correction in accordance with one or more embodiments described herein. Repetitive description of like elements and/or processes employed in respective embodiments is omitted for sake of brevity.

Non-limiting performance results 900 depicts the performance of the decoder described herein (denoted by SYM-LOOP) in comparison to the BP-OSD decoder BB code [[144,12,12]] on 4 qubit errors. As shown, for 4 qubit errors, the SYM-LOOP decoder successfully corrects the errors for all cases where the BP-OSD decoder fails to correct the errors (47 cases), exhibiting a techincal improvement over the BP-OSD decoder.

Non-limiting performance results 910 depicts the performance of the decoder described herein in comparison to the BP-OSD decoder for BB code [[144,12,12]] on 5 qubit errors. As shown, for 5 qubit errors, the SYM-LOOP decoder successfully corrects the errors in 750 cases where the BP-OSD decoder failed, further exhibiting a techincal improvement over the BP-OSD decoder.

As shown in non-limiting performance results 900 and 910, the SYM-LOOP decoder described herein never outputs a full failure (denoted by failure). That is, the decoder will output a success for determining a correction for syndrome 120, or a heralded failure (denoted by invalid) that allows for other corrective actions to be taken. A heralded failure indicates that the decoder did not succeed in determining a correction for syndrome 120. A heralded failure allows for corrective action or different recovery methods as opposed to a full failure where the decoder fails to detect an error or is unable to recover from the error. The decoder described in various embodiments herein never outputs a full failure, and thus allows for other corrective actions to be taken. As shown in non-limiting performance results 900, there are 160 cases where the SYM-LOOP decoder outputs a heralded failure where the BP-OSD decoder succeeds. Further, as shown in non-limiting performance results 910, there are 8,900 cases where the SYM-LOOP decoder outputs a heralded failure where the BP-OSD decoder succeeds. Accordingly, in various embodiments, error correction component 110 can, in some instances, employ the BP-OSD decoder in cases where the SYM-LOOP decoder outputs a heralded failure to significantly improve the success of correcting the errors. This can further be applicable to any number of qubit errors to improve decoding performance. For example, by employing the BP-OSD decoder for the 160 cases where the SYM-LOOP decoder outputs a heralded failure and the BP-OSD decoder succeeds, all cases can be successfully corrected for 4 qubit errors. By employing BP-OSD for the cases than were invalid for the SYM-LOOP decoder, both decoders can complement each other, and enable successful correction of errors where the other decoder is unable to successfully find a correction.

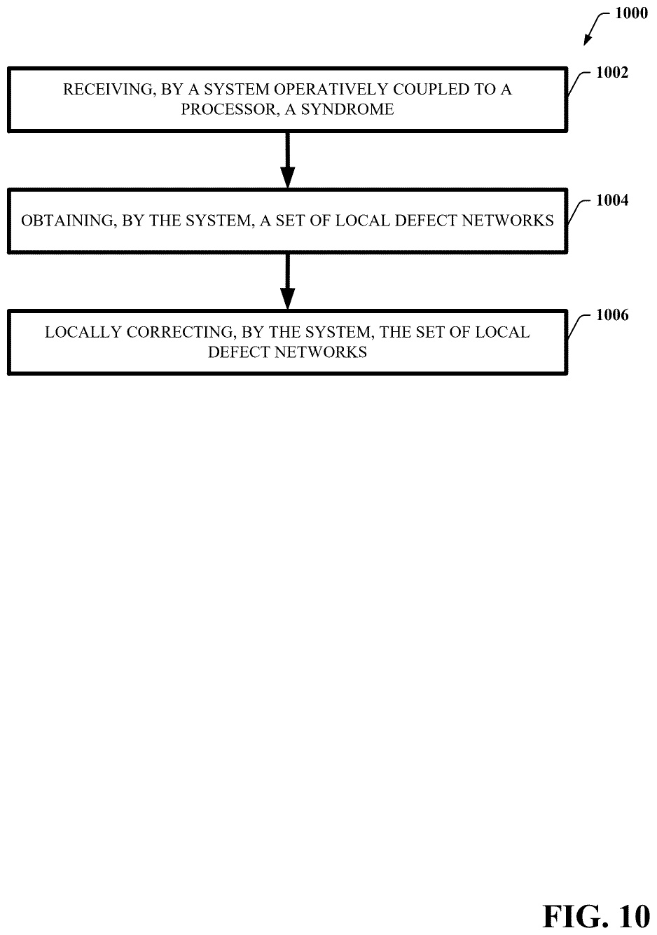

FIG. 10 illustrates a flow diagram of an example, non-limiting method 1000 that can facilitate a decoder for qLDPC codes using matching and local correction in accordance with one or more embodiments described herein. Repetitive description of like elements and/or processes employed in respective embodiments is omitted for sake of brevity.

At 1002, non-limiting method 1000 can comprise selecting (e.g., by matching component 202), by a system operatively coupled to a processor, an auxiliary graph.

At 1004, non-limiting method 1000 can comprise obtaining (e.g., by matching component 202), by the system, a set of local defect networks. In various embodiments, the matching component 202 can determine the set of local defect networks by first determining a set of symmetries of the qLDPC code. Thus, to obtain the set of local defect networks, matching component 202 can match defects across the symmetries to determine how to group the defects into the set of local defect networks.

At 1006, non-limiting method 1000 can comprise locally correcting (e.g., by local correction component 204), by the system, the set of local defect networks. Locally correcting the set of local defect networks can consist of individually correcting each local defect network. Thus, the local corrections of the set of local defect networks can be combined to output a total correction for the syndrome received as input.

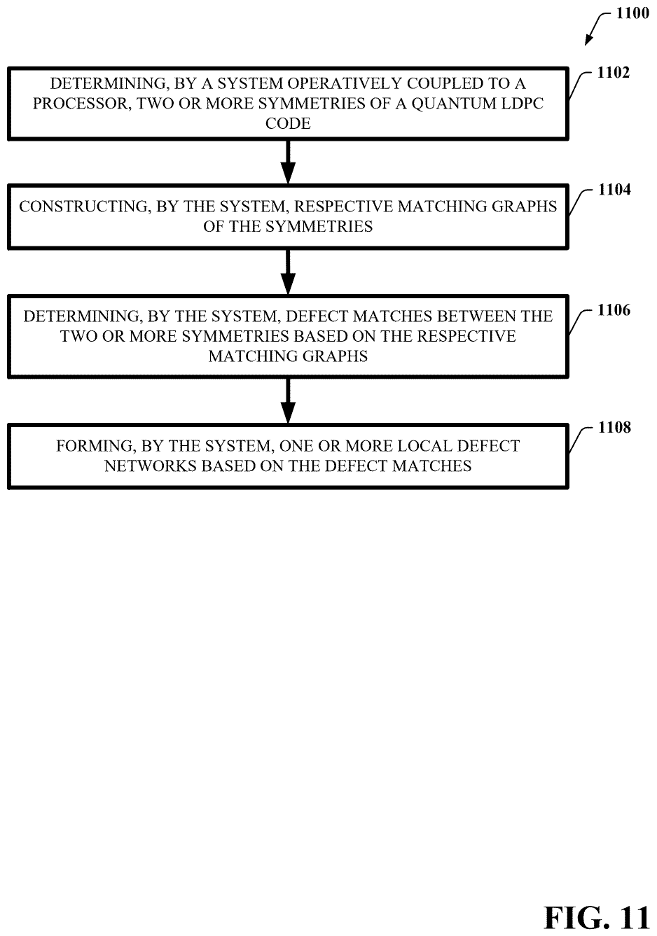

FIG. 11 illustrates a flow diagram of an example, non-limiting method 1100 that can facilitate a decoder for qLDPC codes using matching and local correction in accordance with one or more embodiments described herein. Repetitive description of like elements and/or processes employed in respective embodiments is omitted for sake of brevity.

At 1102, non-limiting method 1100 can comprise determining (e.g., by matching component 202), by a system operatively coupled to a processor, two or more symmetries of a qLDPC code. In various instances, matching component 202 can employ Gaussian elimination to determine the two or more symmetries. For example, matching component 202 can employ Gaussian elimination to determine symmetries of BB codes.

At 1104, non-limiting method 1100 can comprise constructing (e.g., by graph construction component 206), by the system, respective matching graphs of the two or more symmetries.

At 1106, non-limiting method 1100 can comprise determining (e.g., by matching component 202), by the system, defect matches between the two or more symmetries based on the respective matching graphs. In various aspects, matching component 202 can determine a matched defect across any number of the two or more symmetries.

At 1108, non-limiting method 1100 can comprise forming (e.g., by matching component 202), by the system, one or more local defect networks based on the defect matches.

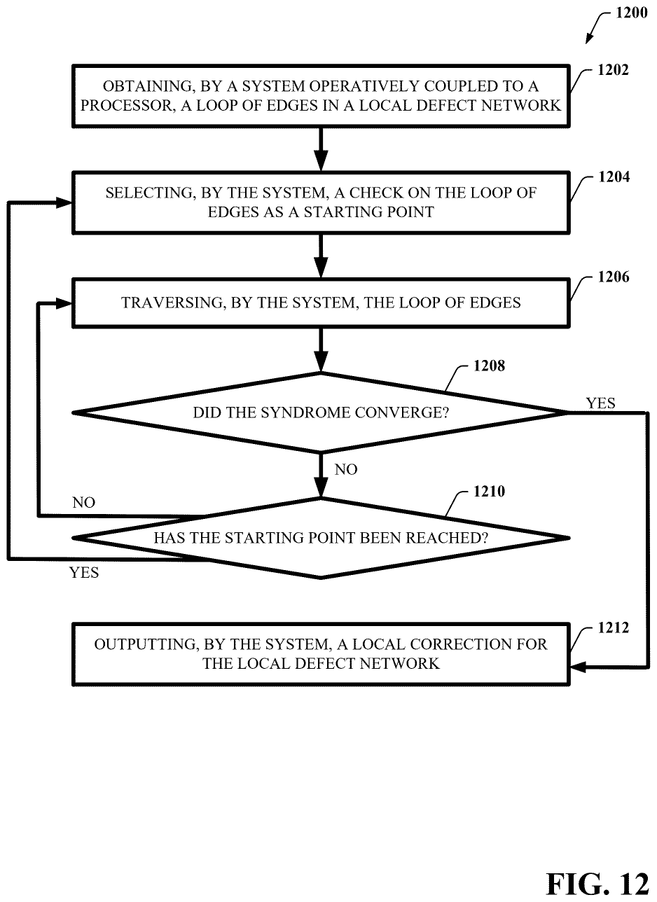

FIG. 12 illustrates a flow diagram of an example, non-limiting method 1200 that can facilitate a decoder for qLDPC codes using matching and local correction in accordance with one or more embodiments described herein. Repetitive description of like elements and/or processes employed in respective embodiments is omitted for sake of brevity.

At 1202, non-limiting method 1200 can comprise obtaining (e.g., by local correction component 204), by a system operatively coupled to a processor, a loop of edges in a local defect network.

At 1204, non-limiting method 1200 can comprise selecting (e.g., by local correction component 204), by the system, a check on the loop of edges as a starting point.

At 1206, non-limiting method 1200 can comprise traversing (e.g., by local correction component 204), by the system, the loop of edges.

At 1208, non-limiting method 1200 can comprise determining (e.g., by local correction component 204), by the system, if the syndrome converged. The syndrome can converge when the defects in the syndrome are cancelled out (e.g., decoder successfully predicts the qubit errors). If no, non-limiting method 1200 can proceed to 1212. If yes, non-limiting method 1200 can proceed to 1210.

At 1210, non-limiting method 1200 can comprise determining (e.g., by local correction component 204), by the system, if the starting point has been reached. If no, non-limiting method 1200 can proceed to 1212. If yes, non-limiting method 1200 can proceed to 1206. If yes, non-limiting method 1200 can proceed to 1212. If yes, non-limiting method 1200 can proceed to 1204.

At 1212, non-limiting method 1200 can comprise outputting (e.g., by local correction component 204), by the system, a local correction operator for the local defect network.

In various embodiments, non-limiting method 1200 can further comprise outputting (e.g., by local correction component 204), by the system, a heralded failure if no correction was determined after traversing all loops in the local defect network, starting from different nodes (checks) in the local defect network.

QEC codes, such as qLDPC codes and BB codes, require efficient and effective decoders to accurately identify and correct errors in a quantum system. Existing decoders of qLDPC codes, such as BP-OSD decoders, can exhibit suboptimal performance at low error rates and sensitivity to error correlations, leading to failures in correcting errors that they are theoretically capable of correcting. BP-OSD decoders can fail to correct errors they are theoretically capable of due to inefficiencies in the OSD stage. In the OSD stage, soft-decision reprocessing can misinterpret the error patterns. This can occur when noise and error correlations cause incorrect reordering or selection of likely errors, leading to the misidentification of the true error configuration despite having the correct syndrome information. Embodiments of the present disclosure introduce a decoder (a decoding algorithm) for qLDPC codes, and particularly BB codes, by matching defects across symmetries to form local defect networks, and locally correcting the local defect networks. It has been demonstrated that local correction of the syndrome can lead to a better performance than existing existing decoders, such as BP-OSD decorders, for BB codes. For instance, the decoder described in the present disclosure can successfully correct the errors that BP-OSD are theoretically capable of correcting but fail to do so. The methods and techniques disclosed herein are based on obtaining symmetries of the qLDPC code and obtaining, via matching, local defect networks based on the symmetries. The methods and techniques disclosed herein are further based on locally correcting the local defect networks to determine a total correction of a syndrome. The decoder described in various embodiments herein can improve logical error rates for handling low error rates, making it a promising decoder that can be applied to qLDPC codes such as BB codes. This can be achieved, as described in the present disclosure, by dividing and addressing smaller segments of the syndrome, which allows for a more targeted and efficient decoding process. This approach improves the decoder's ability to distinguish between errors and noise, as it can focus on specific error patterns without being overwhelmed by the complexity of the entire syndrome. By processing segments independently, the decoder can more effectively utilize available information to identify and correct errors, thereby reducing logical error rates in the presence of low error rates.

FIG. 13 illustrates a block diagram of an example, non-limiting, operating environment 1300 in which one or more embodiments described herein can be facilitated. FIG. 13 and the following discussion are intended to provide a general description of a suitable operating environment 1300 in which one or more embodiments described herein at FIGS. 1-12 can be implemented.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits / lands formed in a major surface of a disc) or any suitable combination of the foregoing. A computer-readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 1300 contains an example of an environment for the execution of at least some of the computer code involved in performing the inventive methods, such as logical operator gauging code 1328. In addition to block 1328, computing environment 1300 includes, for example, computer 1301, wide area network (WAN) 1302, end user device (EUD) 1303, remote server 1304, public cloud 1305, and private cloud 1306. In this embodiment, computer 1301 includes processor set 1310 (including processing circuitry 1320 and cache 1321), communication fabric 1311, volatile memory 1312, persistent storage 1313 (including operating system 1322 and block 1328, as identified above), peripheral device set 1314 (including user interface (UI) device set 1323, storage 1324, and Internet of Things (IoT) sensor set 1325), and network module 1315. Remote server 1304 includes remote database 1330. Public cloud 1305 includes gateway 1340, cloud orchestration module 1341, host physical machine set 1342, virtual machine set 1343, and container set 1344.

COMPUTER 1301 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 1330. As is well understood in the art of computer technology, and depending upon the technology, performance of a computer-implemented method may be distributed among multiple computers and/or between multiple locations. On the other hand, in this presentation of computing environment 1300, detailed discussion is focused on a single computer, specifically computer 1301, to keep the presentation as simple as possible. Computer 1301 may be located in a cloud, even though it is not shown in a cloud in FIG. 13. On the other hand, computer 1301 is not required to be in a cloud except to any extent as may be affirmatively indicated.

PROCESSOR SET 1310 includes one, or more, computer processors of any type now known or to be developed in the future. Processing circuitry 1320 may be distributed over multiple packages, for example, multiple, coordinated integrated circuit chips. Processing circuitry 1320 may implement multiple processor threads and/or multiple processor cores. Cache 1321 is memory that is located in the processor chip package(s) and is typically used for data or code that should be available for rapid access by the threads or cores running on processor set 1310. Cache memories are typically organized into multiple levels depending upon relative proximity to the processing circuitry. Alternatively, some, or all, of the cache for the processor set may be located “off chip.” In some computing environments, processor set 1310 may be designed for working with qubits and performing quantum computing.

Computer-readable program instructions are typically loaded onto computer 1301 to cause a series of operational steps to be performed by processor set 1310 of computer 1301 and thereby effect a computer-implemented method, such that the instructions thus executed will instantiate the methods specified in flowcharts and/or narrative descriptions of computer-implemented methods included in this document (collectively referred to as “the inventive methods”). These computer-readable program instructions are stored in various types of computer-readable storage media, such as cache 1321 and the other storage media discussed below. The program instructions, and associated data, are accessed by processor set 1310 to control and direct performance of the inventive methods. In computing environment 1300, at least some of the instructions for performing the inventive methods may be stored in block 1328 in persistent storage 1313.

COMMUNICATION FABRIC 1311 is the signal conduction path that allows the various components of computer 1301 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

VOLATILE MEMORY 1312 is any type of volatile memory now known or to be developed in the future. Examples include dynamic type random access memory (RAM) or static type RAM. Typically, volatile memory 1312 is characterized by random access, but this is not required unless affirmatively indicated. In computer 1301, the volatile memory 1312 is located in a single package and is internal to computer 1301, but, alternatively or additionally, the volatile memory may be distributed over multiple packages and/or located externally with respect to computer 1301.

PERSISTENT STORAGE 1313 is any form of non-volatile storage for computers that is now known or to be developed in the future. The non-volatility of this storage means that the stored data is maintained regardless of whether power is being supplied to computer 1301 and/or directly to persistent storage 1313. Persistent storage 1313 may be a read only memory (ROM), but typically at least a portion of the persistent storage allows writing of data, deletion of data and re-writing of data. Some familiar forms of persistent storage include magnetic disks and solid state storage devices. Operating system 1322 may take several forms, such as various known proprietary operating systems or open source Portable Operating System Interface-type operating systems that employ a kernel. The code included in block 1328 typically includes at least some of the computer code involved in performing the inventive methods.

PERIPHERAL DEVICE SET 1314 includes the set of peripheral devices of computer 1301. Data communication connections between the peripheral devices and the other components of computer 1301 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 1323 may include components such as a display screen, speaker, microphone, wearable devices (such as goggles and smart watches), keyboard, mouse, printer, touchpad, game controllers, and haptic devices. Storage 1324 is external storage, such as an external hard drive, or insertable storage, such as an SD card. Storage 1324 may be persistent and/or volatile. In some embodiments, storage 1324 may take the form of a quantum computing storage device for storing data in the form of qubits. In embodiments where computer 1301 is required to have a large amount of storage (for example, where computer 1301 locally stores and manages a large database) then this storage may be provided by peripheral storage devices designed for storing very large amounts of data, such as a storage area network (SAN) that is shared by multiple, geographically distributed computers. IoT sensor set 1325 is made up of sensors that can be used in Internet of Things applications. For example, one sensor may be a thermometer and another sensor may be a motion detector.

NETWORK MODULE 1315 is the collection of computer software, hardware, and firmware that allows computer 1301 to communicate with other computers through WAN 1302. Network module 1315 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 1315 are performed on the same physical hardware device. In other embodiments (for example, embodiments that utilize software-defined networking (SDN)), the control functions and the forwarding functions of network module 1315 are performed on physically separate devices, such that the control functions manage several different network hardware devices. Computer-readable program instructions for performing the inventive methods can typically be downloaded to computer 1301 from an external computer or external storage device through a network adapter card or network interface included in network module 1315.

WAN 1302 is any wide area network (for example, the internet) capable of communicating computer data over non-local distances by any technology for communicating computer data, now known or to be developed in the future. In some embodiments, the WAN 1302 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 1303 is any computer system that is used and controlled by an end user (for example, a customer of an enterprise that operates computer 1301), and may take any of the forms discussed above in connection with computer 1301. EUD 1303 typically receives helpful and useful data from the operations of computer 1301. For example, in a hypothetical case where computer 1301 is designed to provide a recommendation to an end user, this recommendation would typically be communicated from network module 1315 of computer 1301 through WAN 1302 to EUD 1303. In this way, EUD 1303 can display, or otherwise present, the recommendation to an end user. In some embodiments, EUD 1303 may be a client device, such as thin client, heavy client, mainframe computer, desktop computer and so on.

REMOTE SERVER 1304 is any computer system that serves at least some data and/or functionality to computer 1301. Remote server 1304 may be controlled and used by the same entity that operates computer 1301. Remote server 1304 represents the machine(s) that collect and store helpful and useful data for use by other computers, such as computer 1301. For example, in a hypothetical case where computer 1301 is designed and programmed to provide a recommendation based on historical data, then this historical data may be provided to computer 1301 from remote database 1330 of remote server 1304.

PUBLIC CLOUD 1305 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 1305 is performed by the computer hardware and/or software of cloud orchestration module 1341. The computing resources provided by public cloud 1305 are typically implemented by virtual computing environments that run on various computers making up the computers of host physical machine set 1342, which is the universe of physical computers in and/or available to public cloud 1305. The virtual computing environments (VCEs) typically take the form of virtual machines from virtual machine set 1343 and/or containers from container set 1344. It is understood that these VCEs may be stored as images and may be transferred among and between the various physical machine hosts, either as images or after instantiation of the VCE. Cloud orchestration module 1341 manages the transfer and storage of images, deploys new instantiations of VCEs and manages active instantiations of VCE deployments. Gateway 1340 is the collection of computer software, hardware, and firmware that allows public cloud 1305 to communicate through WAN 1302.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 1306 is similar to public cloud 1305, except that the computing resources are only available for use by a single enterprise. While private cloud 1306 is depicted as being in communication with WAN 1302, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 1305 and private cloud 1306 are both part of a larger hybrid cloud.

CLOUD COMPUTING SERVICES AND/OR MICROSERVICES (not separately shown in FIG. 13): private and public clouds 1306 are programmed and configured to deliver cloud computing services and/or microservices (unless otherwise indicated, the word “microservices” shall be interpreted as inclusive of larger “services” regardless of size). Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider's systems, and back. In some embodiments, cloud services may be configured and orchestrated according to as “as a service” technology paradigm where something is being presented to an internal or external customer in the form of a cloud computing service. As-a-Service offerings typically provide endpoints with which various customers interface. These endpoints are typically based on a set of APIs. One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks.

The embodiments described herein can be directed to one or more of a system, a method, an apparatus and/or a computer program product at any possible technical detail level of integration. The computer program product can include a computer readable storage medium (or media) having computer readable program instructions thereon for causing a processor to carry out aspects of the one or more embodiments described herein. The computer readable storage medium can be a tangible device that can retain and store instructions for use by an instruction execution device. The computer readable storage medium can be, for example, but is not limited to, an electronic storage device, a magnetic storage device, an optical storage device, an electromagnetic storage device, a superconducting storage device and/or any suitable combination of the foregoing. A non-exhaustive list of more specific examples of the computer readable storage medium can also include the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon and/or any suitable combination of the foregoing. A computer readable storage medium, as used herein, is not to be construed as being transitory signals per se, such as radio waves and/or other freely propagating electromagnetic waves, electromagnetic waves propagating through a waveguide and/or other transmission media (e.g., light pulses passing through a fiber-optic cable), and/or electrical signals transmitted through a wire.

Computer readable program instructions described herein can be downloaded to respective computing/processing devices from a computer readable storage medium and/or to an external computer or external storage device via a network, for example, the Internet, a local area network, a wide area network and/or a wireless network. The network can comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device. Computer readable program instructions for carrying out operations of the one or more embodiments described herein can be assembler instructions, instruction-set-architecture (ISA) instructions, machine instructions, machine dependent instructions, microcode, firmware instructions, state-setting data, configuration data for integrated circuitry, and/or source code and/or object code written in any combination of one or more programming languages, including an object oriented programming language such as Smalltalk, C++ or the like, and/or procedural programming languages, such as the “C” programming language and/or similar programming languages. The computer readable program instructions can execute entirely on a computer, partly on a computer, as a stand-alone software package, partly on a computer and/or partly on a remote computer or entirely on the remote computer and/or server. In the latter scenario, the remote computer can be connected to a computer through any type of network, including a local area network (LAN) and/or a wide area network (WAN), and/or the connection can be made to an external computer (for example, through the Internet using an Internet Service Provider). In one or more embodiments, electronic circuitry including, for example, programmable logic circuitry, field-programmable gate arrays (FPGA) and/or programmable logic arrays (PLA) can execute the computer readable program instructions by utilizing state information of the computer readable program instructions to personalize the electronic circuitry, in order to perform aspects of the one or more embodiments described herein.

Aspects of the one or more embodiments described herein are described with reference to flowchart illustrations and/or block diagrams of methods, apparatus (systems), and computer program products according to one or more embodiments described herein. It will be understood that each block of the flowchart illustrations and/or block diagrams, and combinations of blocks in the flowchart illustrations and/or block diagrams, can be implemented by computer readable program instructions. These computer readable program instructions can be provided to a processor of a general-purpose computer, special purpose computer and/or other programmable data processing apparatus to produce a machine, such that the instructions, which execute via the processor of the computer or other programmable data processing apparatus, can create means for implementing the functions/acts specified in the flowchart and/or block diagram block or blocks. These computer readable program instructions can also be stored in a computer readable storage medium that can direct a computer, a programmable data processing apparatus and/or other devices to function in a particular manner, such that the computer readable storage medium having instructions stored therein can comprise an article of manufacture including instructions which can implement aspects of the function/act specified in the flowchart and/or block diagram block or blocks. The computer readable program instructions can also be loaded onto a computer, other programmable data processing apparatus and/or other device to cause a series of operational acts to be performed on the computer, other programmable apparatus and/or other device to produce a computer implemented process, such that the instructions which execute on the computer, other programmable apparatus and/or other device implement the functions/acts specified in the flowchart and/or block diagram block or blocks.

The flowcharts and block diagrams in the figures illustrate the architecture, functionality and/or operation of possible implementations of systems, computer-implementable methods and/or computer program products according to one or more embodiments described herein. In this regard, each block in the flowchart or block diagrams can represent a module, segment and/or portion of instructions, which comprises one or more executable instructions for implementing the specified logical function. In one or more alternative implementations, the functions noted in the blocks can occur out of the order noted in the Figures. For example, two blocks shown in succession can be executed substantially concurrently, and/or the blocks can sometimes be executed in the reverse order, depending upon the functionality involved. It will also be noted that each block of the block diagrams and/or flowchart illustration, and/or combinations of blocks in the block diagrams and/or flowchart illustration, can be implemented by special purpose hardware-based systems that can perform the specified functions and/or acts and/or carry out one or more combinations of special purpose hardware and/or computer instructions.

While the subject matter has been described above in the general context of computer-executable instructions of a computer program product that runs on a computer and/or computers, those skilled in the art will recognize that the one or more embodiments herein also can be implemented at least partially in parallel with one or more other program modules. Generally, program modules include routines, programs, components and/or data structures that perform particular tasks and/or implement particular abstract data types. Moreover, the aforedescribed computer-implemented methods can be practiced with other computer system configurations, including single-processor and/or multiprocessor computer systems, mini-computing devices, mainframe computers, as well as computers, hand-held computing devices (e.g., PDA, phone), and/or microprocessor-based or programmable consumer and/or industrial electronics. The illustrated aspects can also be practiced in distributed computing environments in which tasks are performed by remote processing devices that are linked through a communications network. However, one or more, if not all aspects of the one or more embodiments described herein can be practiced on stand-alone computers. In a distributed computing environment, program modules can be located in both local and remote memory storage devices.

As used in this application, the terms “component,” “system,” “platform” and/or “interface” can refer to and/or can include a computer-related entity or an entity related to an operational machine with one or more specific functionalities. The entities described herein can be either hardware, a combination of hardware and software, software, or software in execution. For example, a component can be, but is not limited to being, a process running on a processor, a processor, an object, an executable, a thread of execution, a program and/or a computer. By way of illustration, both an application running on a server and the server can be a component. One or more components can reside within a process and/or thread of execution and a component can be localized on one computer and/or distributed between two or more computers. In another example, respective components can execute from various computer readable media having various data structures stored thereon. The components can communicate via local and/or remote processes such as in accordance with a signal having one or more data packets (e.g., data from one component interacting with another component in a local system, distributed system and/or across a network such as the Internet with other systems via the signal). As another example, a component can be an apparatus with specific functionality provided by mechanical parts operated by electric or electronic circuitry, which is operated by a software and/or firmware application executed by a processor. In such a case, the processor can be internal and/or external to the apparatus and can execute at least a part of the software and/or firmware application. As yet another example, a component can be an apparatus that provides specific functionality through electronic components without mechanical parts, where the electronic components can include a processor and/or other means to execute software and/or firmware that confers at least in part the functionality of the electronic components. In an aspect, a component can emulate an electronic component via a virtual machine, e.g., within a cloud computing system.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter described herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

As it is employed in the subject specification, the term “processor” can refer to substantially any computing processing unit and/or device comprising, but not limited to, single-core processors; single-processors with software multithread execution capability; multi-core processors; multi-core processors with software multithread execution capability; multi-core processors with hardware multithread technology; parallel platforms; and/or parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, and/or any combination thereof designed to perform the functions described herein. Further, processors can exploit nano-scale architectures such as, but not limited to, molecular and quantum-dot based transistors, switches and/or gates, in order to optimize space usage and/or to enhance performance of related equipment. A processor can be implemented as a combination of computing processing units.

Herein, terms such as “store,” “storage,” “data store,” data storage,” “database,” and substantially any other information storage component relevant to operation and functionality of a component are utilized to refer to “memory components,” entities embodied in a “memory,” or components comprising a memory. Memory and/or memory components described herein can be either volatile memory or nonvolatile memory or can include both volatile and nonvolatile memory. By way of illustration, and not limitation, nonvolatile memory can include read only memory (ROM), programmable ROM (PROM), electrically programmable ROM (EPROM), electrically erasable ROM (EEPROM), flash memory and/or nonvolatile random-access memory (RAM) (e.g., ferroelectric RAM (FeRAM). Volatile memory can include RAM, which can act as external cache memory, for example. By way of illustration and not limitation, RAM can be available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), direct Rambus RAM (DRRAM), direct Rambus dynamic RAM (DRDRAM) and/or Rambus dynamic RAM (RDRAM). Additionally, the described memory components of systems and/or computer-implemented methods herein are intended to include, without being limited to including, these and/or any other suitable types of memory.

What has been described above includes mere examples of systems and computer-implemented methods. It is, of course, not possible to describe every conceivable combination of components and/or computer-implemented methods for purposes of describing the one or more embodiments, but one of ordinary skill in the art can recognize that many further combinations and/or permutations of the one or more embodiments are possible. Furthermore, to the extent that the terms “includes,” “has,” “possesses,” and the like are used in the detailed description, claims, appendices and/or drawings such terms are intended to be inclusive in a manner similar to the term “comprising” as “comprising” is interpreted when employed as a transitional word in a claim.

The descriptions of the various embodiments have been presented for purposes of illustration but are not intended to be exhaustive or limited to the embodiments described herein. Many modifications and variations will be apparent to those of ordinary skill in the art without departing from the scope and spirit of the described embodiments. The terminology used herein was chosen to best explain the principles of the embodiments, the practical application and/or technical improvement over technologies found in the marketplace, and/or to enable others of ordinary skill in the art to understand the embodiments described herein.

What is claimed is:

1. A system, comprising:
a memory that stores computer executable components; and
a processor that executes the computer executable components stored in the memory, wherein the computer executable components comprise:
an error correction component that corrects, via a decoder, qubit errors for quantum low-density parity-check (qLDPC) code, wherein correcting qubit errors for the qLDPC code via the decoder comprises:
obtaining a set of local defect networks in a syndrome by matching defects on symmetries of the qLDPC code, wherein the symmetries comprise a subset of checks of the qLDPC code such that each qubit error creates an even number of defects; and
locally correcting one or more of the set of local defect networks.

2. The system of claim 1, further comprising:
a graph construction component that constructs matching graphs from the symmetries, wherein edges in the matching graphs represent qubit errors, and wherein vertices in the matching graphs represent checks of the qLDPC code.

3. The system of claim 2, wherein the graph construction component obtains the symmetries from the qLDPC code using Gaussian elimination on a parity check matrix of the qLDPC code.

4. The system of claim 1, wherein obtaining the set of local defect networks comprises:
matching the defects from different symmetries; and
combining the defects to form the set of local defect networks, wherein defects that share a qubit are in a same local defect network.

5. The system of claim 1, wherein locally correcting one or more of the set of local defect networks comprises:
obtaining a loop of edges in a local defect network;
selecting a check on the loop of edges;
traversing the loop of edges starting from the check to determine a correction operator.

6. The system of claim 5, wherein the error correction component includes edges from the loop of edges in the correction operator if it cancels defects in the syndrome.

7. The system of claim 5, wherein the error correction component traverses the loop of edges starting from different checks on the loop of edges until the qubit errors match the defects.

8. The system of claim 5, wherein the correction operator is a Pauli operator that corrects the defects in the local defect network.

9. The system of claim 2, wherein the error correction component matches, based on the matching graphs, the defects via minimum-weight perfect matching, union-find decoding, weighted union-find decoding, clustering, or belief matching.

10. A computer-implemented method, comprising:
correcting, by a system operatively coupled to a processor, qubit errors for quantum low-density parity-check (qLDPC) code via a decoder, wherein correcting qubit errors for the qLDPC code via the decoder comprises;
obtaining, by the system, a set of local defect networks in a syndrome by matching defects on symmetries of the qLDPC code, wherein the symmetries comprise a subset of checks of the qLDPC code such that each qubit error creates an even number of defects; and
locally correcting, by the system, one or more of the set of local defect networks.

11. The computer-implemented method of claim 10, further comprising:
constructing, by the system, matching graphs from the symmetries, wherein edges in the matching graphs represent qubit errors, and wherein vertices in the matching graphs represent checks of the qLDPC code.

12. The computer-implemented method of claim 11, further comprising:
obtaining, by the system, the symmetries from the qLDPC code using Gaussian elimination on a parity check matrix of the qLDPC code.

13. The computer-implemented method of claim 10, wherein obtaining the set of local defect networks comprises:
matching the defects from different symmetries; and
combining the defects to form the set of local defect networks, wherein defects that share a qubit are in a same local defect network.

14. The computer-implemented method of claim 10, wherein locally correcting one or more of the set of local defect networks comprises:
obtaining a loop of edges in a local defect network;
selecting a check on the loop of edges;
traversing the loop of edges starting from the check to determine a correction operator.

15. The computer-implemented method of claim 14, further comprising:
including, by the system, edges from the loop of edges in the correction operator if it cancels defects in the syndrome.

16. The computer-implemented method of claim 14, further comprising:
traversing, by the system, the loop of edges starting from different checks on the loop of edges until the qubit errors match the defects.

17. The computer-implemented method of claim 14, wherein the correction operator is a Pauli operator that corrects the defects in the local defect network.

18. The computer-implemented method of claim 11, further comprising:
matching, by the system. and based on the matching graphs, the defects via minimum-weight perfect matching, union-find decoding, weighted union-find decoding, clustering, or belief matching.

19. A computer program product for decoding, the computer program product comprising a computer readable storage medium having program instructions embodied therewith, the program instructions executable by a processor to cause the processor to:
correct, by the processor, qubit errors for quantum low-density parity-check (qLDPC) code via a decoder, wherein correcting qubit errors for the qLDPC code via the decoder comprises;
obtaining, by the processor, a set of local defect networks in a syndrome by the on symmetries of the qLDPC code, wherein the symmetries comprise a subset of checks of the qLDPC code such that each qubit error creates an even number of defects; and
locally correcting, by the processor, one or more of the set of local defect networks.

20. The computer program product of claim 19, wherein obtaining the set of local defect networks comprises:
matching the defects from different symmetries; and
combining the defects to form the set of local defect networks, wherein defects that share a qubit are in a same local defect network.
